(19) United States
(12) Patent Application Publication
(10) Pub. No.: US 2024/0006843 A1
(43) Pub. Date: Jan. 4, 2024

(54) SEMICONDUCTOR LASER LIGHT-EMITTING DEVICE AND METHOD FOR MANUFACTURING SEMICONDUCTOR LASER LIGHT-EMITTING DEVICE

(71) Applicant: Nuvoton Technology Corporation Japan, Kyoto (JP)

(72) Inventors: Masanori HIROKI, Shiga (JP); Hiroki SHIROZONO, Toyama (JP); Shigeo HAYASHI, Kyoto (JP)

(21) Appl. No.: 18/467,534

(22) Filed: Sep. 14, 2023

Related U.S. Application Data
(63) Continuation of application No. PCT/JP2022/010699, filed on Mar. 10, 2022.

(30) Foreign Application Priority Data
Mar. 26, 2021 (JP) 2021-054143

(51) Int. Cl. H01S 5/024; H01S 5/02315; H01S 5/02325; H01S 5/02355

(52) U.S. Cl. CPC H01S 5/02469; H01S 5/02315; H01S 5/02325; H01S 5/02355

(57) ABSTRACT

A semiconductor laser light-emitting device includes: a mounting base (mounting substrate); a submount disposed above the mounting base; a connecting member that connects the mounting base and the submount and is composed of a porous metal material; and a semiconductor laser disposed above the submount. The submount includes a front face that is a face on the light emission side of the semiconductor laser. The connecting member includes a peripheral portion that continuously covers at least part of the front face of the submount and the peripheral area of a first area of the top surface of the mounting base, where the first area corresponds to the submount. The top surface of the peripheral portion is straight or recessed at a cross section that intersects the front face of the submount and the top surface of the mounting base.

### CROSS REFERENCE TO RELATED APPLICATIONS

This is a continuation application of PCT International Application No. PCT/JP2022/010699 filed on Mar. 10, 2022, designating the United States of America, which is based on and claims priority of Japanese Patent Application No. 2021-054143 filed on Mar. 26, 2021. The entire disclosures of the above-identified applications, including the specifications, drawings and claims are incorporated herein by reference in their entirety.

### FIELD

The present disclosure relates to a semiconductor laser light-emitting device including a semiconductor laser, and a method for manufacturing the semiconductor laser light-emitting device.

### BACKGROUND

Semiconductor laser light-emitting devices are used as light sources for products in various fields, such as projectors, in-vehicle headlights, and laser processing devices. A semiconductor laser light-emitting device of this type includes, for example, a substrate that is a mounting base, a submount mounted on the substrate, and a semiconductor laser (i.e., a semiconductor laser element) mounted on the submount (see PTL 1, for example).

### CITATION LIST

### Patent Literature

PTL 1: Japanese Unexamined Patent Application Publication No. 2015-228401

### SUMMARY

### Technical Problem

There has been a demand for high-power semiconductor laser light-emitting devices, but in recent years, increased output of semiconductor laser-emitting devices has been desired.

One conceivable way to increase the output of a semiconductor laser light-emitting device is to increase current flowing through a semiconductor laser to significantly increase the current in the semiconductor laser, or to use a plurality of semiconductor lasers to form a multichip semiconductor laser light-emitting device.

However, when current flowing through the semiconductor laser is increased or a plurality of semiconductor lasers are used, the amount of heat generated at the semiconductor laser increases and the temperature of the semiconductor laser increases, and this reduces the output of a laser beam emitted from the semiconductor laser or reduces the reliability of the semiconductor laser.

For this reason, it is a challenge, when increasing the output of the semiconductor laser light-emitting device, to efficiently conduct heat generated at the semiconductor laser to the mounting base. It is also a challenge to reduce interference between components of the semiconductor laser light-emitting device, such as the submount, and a laser beam emitted from the semiconductor laser.

The present disclosure is conceived to overcome such problems as described above and has an object to provide, for instance, a semiconductor laser light-emitting device capable of efficiently conducting heat generated at the semiconductor laser to the mounting base via the submount and reducing interference between a laser beam emitted from the semiconductor laser and components around the semiconductor laser.

### Solution to Problem

To achieve the above object, a semiconductor laser light-emitting device according to one aspect of the present disclosure includes: a mounting base; a submount disposed above the mounting base; a connecting member that connects the mounting base and the submount and is composed of a porous metal material; and a semiconductor laser disposed above the submount. The submount includes a front face that is a face on the light emission side of the semiconductor laser. The connecting member includes a peripheral portion that continuously covers at least part of the front face of the submount and the peripheral area of a first area of the top surface of the mounting base, where the first area corresponds to the submount. The top surface of the peripheral portion is straight or recessed at a cross section that intersects the front face of the submount and the top surface of the mounting base.

To achieve the above object, a semiconductor laser light-emitting device according to another aspect of the present disclosure includes: a mounting base; a submount disposed above the mounting base; a connecting member that connects the mounting base and the submount and is composed of a porous metal material; a semiconductor laser disposed above the submount; and a mirror that reflects emission light from the semiconductor laser. The submount includes a front face that is a face on the light emission side of the semiconductor laser. The mirror is disposed above the mounting base and facing the front face of the submount. The connecting member includes a peripheral portion that continuously covers at least part of the front face of the submount, the peripheral area of a first area of the top surface of the mounting base, and an end portion of the mirror, where the first area corresponds to the submount, and the end portion faces the front face of the submount. The distance from the end portion of the mirror to the front face of the submount is less than the distance from a bottom surface of the submount to the top surface of the submount. The top surface of the peripheral portion is straight or recessed at a cross section that intersects the front face of the submount, the top surface of the mounting base, and the mirror.

To achieve the above object, a semiconductor laser light-emitting device according to yet another aspect of the present disclosure includes: a mounting base; a submount disposed above the mounting base; a connecting member that connects the mounting base and the submount and is composed of a porous metal material; and a semiconductor laser disposed above the submount. The submount includes a front face that is a face on the light emission side of the semiconductor laser. The connecting member includes a peripheral portion that continuously covers at least part of the front face of the submount and the peripheral area of a first area of the top surface of the mounting base, where the first area corresponds to the submount. The distance from the bottom surface of the submount to a position at which the top surface of the peripheral portion contacts the front face of the submount is largest below the optical axis of the semiconductor laser.

To achieve the above object, a method for manufacturing a semiconductor laser light-emitting device according to one aspect of the present disclosure includes: providing a semiconductor laser on the top surface of a submount; applying first metal particles having a first particle size to the top surface of a mounting base; disposing the submount on the first metal particles and disposing the first metal particles so as to contact the front face of the submount, where the front face is a face on the light emission side of the semiconductor laser; and applying second metal particles having a second particle size to the first metal particles.

### Advantageous Effects

According to the present disclosure, heat generated at the semiconductor laser can be efficiently conducted to the mounting base via the submount, and interference between a laser beam emitted from the semiconductor laser and components around the semiconductor laser can be reduced.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a schematic perspective view of a semiconductor laser light-emitting device according to Embodiment 1.

FIG. 2 is a schematic cross-sectional view of the semiconductor laser light-emitting device according to Embodiment 1.

FIG. 3 is a schematic magnified cross-sectional view of the microscopic structure of a connecting member according to Embodiment 1.

FIG. 4 is a perspective view of the configuration of the semiconductor laser light-emitting device according to Embodiment 1 and used in a simulation.

FIG. 5 is a cross-sectional view of the configuration of the semiconductor laser light-emitting device according to Embodiment 1 and used in the simulation.

FIG. 6 is a cross-sectional view of the configuration of a semiconductor laser light-emitting device according to a comparative example and used in the simulation.

FIG. 7 is a schematic cross-sectional view of the shape of the peripheral portion of the connecting member in the semiconductor laser light-emitting device according to Embodiment 1.

FIG. 8 is a schematic perspective view of the heat conduction region in a heat diffusion model for diffusing heat from a semiconductor laser according to Embodiment 1 to a submount.

FIG. 9 is a schematic perspective view illustrating one example of the shape of the peripheral portion according to Embodiment 1.

FIG. 10A is a schematic cross-sectional view illustrating a first process of a first manufacturing method of the semiconductor laser light-emitting device according to Embodiment 1.

FIG. 10B is a schematic cross-sectional view illustrating a second process of the first manufacturing method of the semiconductor laser light-emitting device according to Embodiment 1.

FIG. 10C is a schematic cross-sectional view illustrating a third process of the first manufacturing method of the semiconductor laser light-emitting device according to Embodiment 1.

FIG. 10D is a schematic cross-sectional view illustrating a fourth process of the first manufacturing method of the semiconductor laser light-emitting device according to Embodiment 1.

FIG. 10E is a schematic cross-sectional view illustrating a fifth process of the first manufacturing method of the semiconductor laser light-emitting device according to Embodiment 1.

FIG. 10F is a schematic cross-sectional view illustrating a sixth process of the first manufacturing method of the semiconductor laser light-emitting device according to Embodiment 1.

FIG. 11A is a schematic plan view illustrating the first process of the first manufacturing method of the semiconductor laser light-emitting device according to Embodiment 1.

FIG. 11B is a schematic plan view illustrating the second process of the first manufacturing method of the semiconductor laser light-emitting device according to Embodiment 1.

FIG. 11C is a schematic plan view illustrating the fourth process of the first manufacturing method of the semiconductor laser light-emitting device according to Embodiment 1.

FIG. 11D is a schematic plan view illustrating the fifth process of the first manufacturing method of the semiconductor laser light-emitting device according to Embodiment 1.

FIG. 12A is a schematic cross-sectional view illustrating a first process of a second manufacturing method of the semiconductor laser light-emitting device according to Embodiment 1.

FIG. 12B is a schematic cross-sectional view illustrating a second process of the second manufacturing method of the semiconductor laser light-emitting device according to Embodiment 1.

FIG. 12C is a schematic cross-sectional view illustrating a third process of the second manufacturing method of the semiconductor laser light-emitting device according to Embodiment 1.

FIG. 12D is a schematic cross-sectional view illustrating a fourth process of the second manufacturing method of the semiconductor laser light-emitting device according to Embodiment 1.

FIG. 12E is a schematic cross-sectional view illustrating a fifth process of the second manufacturing method of the semiconductor laser light-emitting device according to Embodiment 1.

FIG. 13A is a schematic cross-sectional view illustrating a first process of a third manufacturing method of the semiconductor laser light-emitting device according to Embodiment 1.

FIG. 13B is a schematic cross-sectional view illustrating a second process of the third manufacturing method of the semiconductor laser light-emitting device according to Embodiment 1.

FIG. 13C is a schematic cross-sectional view illustrating a third process of the third manufacturing method of the semiconductor laser light-emitting device according to Embodiment 1.

FIG. 14A illustrates one example of an electron microscopic photo showing a cross section of the connecting member according to Embodiment 1.

FIG. 14B illustrates a graph showing the gradation distribution of an image taken at line A-B in the electron microscopic photo illustrated in FIG. 14A.

FIG. 14C illustrates the gradation histogram of the image taken at line A-B in the electron microscopic photo illustrated in FIG. 14A.

FIG. 15 is a schematic perspective view of a semiconductor laser light-emitting device according to Embodiment 2.

FIG. 16 is a schematic cross-sectional view of the semiconductor laser light-emitting device according to Embodiment 2.

### DESCRIPTION OF EMBODIMENTS

Hereinafter, embodiments of the present disclosure will be described in detail with reference to the drawings. Note that each of the embodiments described below shows a specific example of the present disclosure. Accordingly, numerical values, shapes, materials, elements, the arrangement and connection of the elements, steps (processes), an order of the steps, etc., indicated in the following embodiments are mere examples, and do not intend to limit the present disclosure.

The figures are schematic diagrams and are not necessarily precise illustrations. Accordingly, the figures are not necessarily to scale. Substantially identical elements in the drawings are assigned with like reference signs, and redundant description is omitted or simplified.

### Embodiment 1

A semiconductor laser light-emitting device according to Embodiment 1 and a method for manufacturing the semiconductor laser light-emitting device will be described.

### [1-1. Overall Configuration]

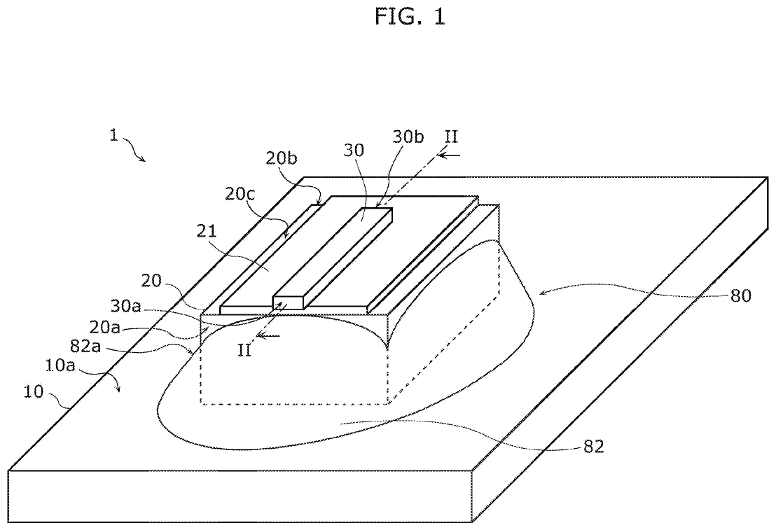

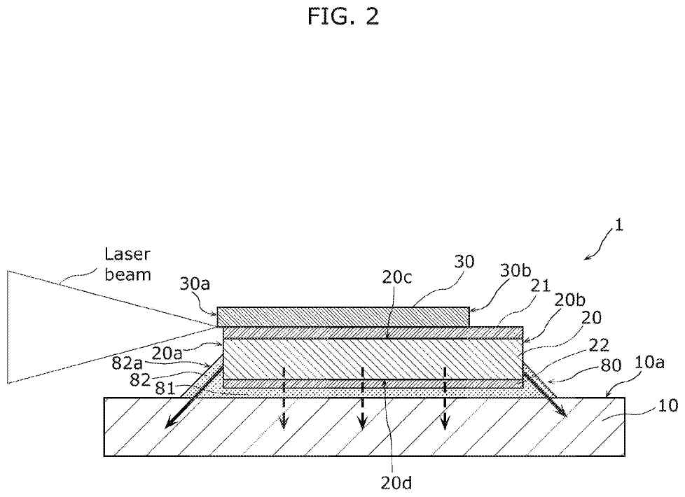

First, the overall configuration of semiconductor laser light-emitting device 1 according to the present embodiment will be described with reference to FIG. 1 and FIG. 2. FIG. 1 is a schematic perspective view of semiconductor laser light-emitting device 1 according to the present embodiment. FIG. 2 is a schematic cross-sectional view of semiconductor laser light-emitting device 1. FIG. 2 illustrates a cross section taken at line II-II in FIG. 1. Stated differently, FIG. 2 illustrates a cross section that passes through the optical axis of semiconductor laser light-emitting device 1 and is perpendicular to top surface 10a of mounting substrate 10.

As illustrated in FIG. 1 and FIG. 2, semiconductor laser light-emitting device 1 includes mounting substrate 10, submount 20, connecting member 80, and semiconductor laser 30. In the present embodiment, semiconductor laser light-emitting device 1 also includes electrode 21 and spacer 22, as illustrated in FIG. 2.

Mounting substrate 10 is one example of a mounting base for mounting semiconductor laser 30 and submount 20. Specifically, submount 20 on which semiconductor laser 30 is mounted is mounted on mounting substrate 10.

As illustrated in FIG. 1 and FIG. 2, mounting substrate 10 is flat on the whole. In the present embodiment, submount 20 is mounted on top surface 10a that is one of principal surfaces of mounting substrate 10. In other words, top surface 10a is a mounting surface on which submount 20 is mounted. The shape of mounting substrate 10 in top view (i.e., the shape of top surface 10a) is, for example, rectangular, but is not limited to this example. In the present embodiment, plate-like mounting substrate 10 is used as the mounting base, but the shape of the mounting base is not limited to be plate-like. The shape of the mounting base may be, for example, a cuboid.

The material of mounting substrate 10 is, for example, a metal material, a ceramic material, a glass material, or a resin material. To efficiently conduct heat generated at semiconductor laser 30 to mounting substrate 10 via submount 20, mounting substrate 10 may be composed of a material, such as a metal material, which has a high thermal conductivity. A metal material that has a high thermal conductivity and is practical as mounting substrate 10 is, for example, Cu or Al. In the present embodiment, mounting substrate 10 is a Cu substrate composed of Cu.

Submount 20 is a base disposed above mounting substrate 10. Submount 20 supports semiconductor laser 30. In the present embodiment, semiconductor laser 30 is disposed on submount 20. In other words, semiconductor laser 30 is located on submount 20. As described above, submount 20 is mounted on top surface 10a of mounting substrate 10. Submount 20 is thus located between mounting substrate 10 and semiconductor laser 30. Stated differently, submount 20 and semiconductor laser 30 are stacked on mounting substrate 10 in this order.

Submount 20 functions also as a heatsink for dissipating heat generated at semiconductor laser 30. The material of submount 20 may be therefore either a conductive material or an insulating material, but submount 20 may be composed of a material with a high thermal conductivity. The thermal conductivity of submount 20 may be, for example, at least 150 w/(m*K). Submount 20 is composed of, for example, a ceramic material such as aluminum nitride (AlN) or polycrystalline silicon carbide (SiC), a metal material such as Cu, or diamond such as monocrystalline diamond or polycrystalline diamond. In the present embodiment, submount 20 is composed of AlN. The shape of submount 20 is, for example, a rectangular plate-like cuboid, but is not limited to this example.

Submount 20 includes front face 20a that is a face on the light emission side of semiconductor laser 30 and rear face 20b that is a face on the side opposite to the light emission side of semiconductor laser 30 (i.e., the rear face of submount 20 relative to front face 20a). Submount 20 also includes top surface 20c on which semiconductor laser 30 is mounted and bottom surface 20d facing mounting substrate 10. Front face 20a of submount 20 is the front end face of submount 20 and rear face 20b of submount 20 is the rear end face of submount 20. In the present embodiment, since the shape of submount 20 is rectangular plate-like, the shapes of front face 20a and rear face 20b of submount 20 are rectangular. Moreover, front face 20a and rear face 20b of submount 20 are parallel to each other. As used herein, the term “parallel” does not limitedly mean being parallel in a strict sense and includes being approximately parallel with a deviation of 5 degrees or less from the state of being parallel.

Electrode 21 is a conductive member disposed on top surface 20c of submount 20. Electrode 21 is composed of, for example, a conductive material such as a metal material. In the present embodiment, electrode 21 is a Cu electrode composed of Cu and having a thickness of 50 μm. Electrode 21 may be composed of a single conductive film or a plurality of conductive films.

Spacer 22 is disposed between top surface 10a of mounting substrate 10 and bottom surface 20d of submount 20. Top surface 10a of mounting substrate 10 and bottom surface 20d of submount 20 are parallel to each other.

Spacer 22 is a film component having a constant thickness. The top surface of spacer 22 has a shape that is approximately same as the shape of bottom surface 20d of submount 20, and is disposed on the approximately entire surface of bottom surface 20d. The thickness of spacer 22 is not specifically limited. In the present embodiment, the thickness of spacer 22 is 50 μm. The material of spacer 22 may be either a conductive material or an insulating material, but may be composed of a material with a high thermal conductivity. This makes it possible to efficiently conduct heat generated at semiconductor laser 30 to mounting substrate 10 via submount 20 and spacer 22. Spacer 22 is, for example, a metal film made of a metal material such as Cu or Al.

Semiconductor laser 30 is an element that is disposed above submount 20 and emits a laser beam. Semiconductor laser 30 includes: front end face 30a that is an end face on the side from which the laser beam is emitted; and rear end face 30b that is an end face on the rear side opposite to the side on which front end face 30a is located. Semiconductor laser 30 includes also an optical waveguide formed between front end face 30a and rear end face 30b.

Semiconductor laser 30 is elongated with a resonator length direction (i.e., the optical axis direction of the laser beam) being defined as the longitudinal direction of semiconductor laser 30. The length of semiconductor laser 30 in the resonator length direction is, for example, 1200 μm, but is not limited to this example.

Semiconductor laser 30 is mounted on the top surface of submount 20. Specifically, semiconductor laser 30 is mounted on electrode 21 on submount 20. In the present embodiment, semiconductor laser 30 is junction-down mounted on submount 20. The mounting mode of semiconductor laser 30 is not limited to this and semiconductor laser 30 may be junction-up mounted on submount 20.

Semiconductor laser 30 is mounted in such a manner that front end face 30a sticks out from front face 20a of submount 20. In other words, semiconductor laser 30 protrudes from front face 20a of submount 20, and front end face 30a of semiconductor laser 30 is located farther in the light emission direction of the semiconductor laser from front face 20a of submount 20. The protrusion amount of semiconductor laser 30 (i.e., the distance from front face 20a of submount 20 to front end face 30a of semiconductor laser 30) is, for example, 5 μm to 20 μm, inclusive, but is not limited to this example. In the present embodiment, the protrusion amount of semiconductor laser 30 is 10 μm.

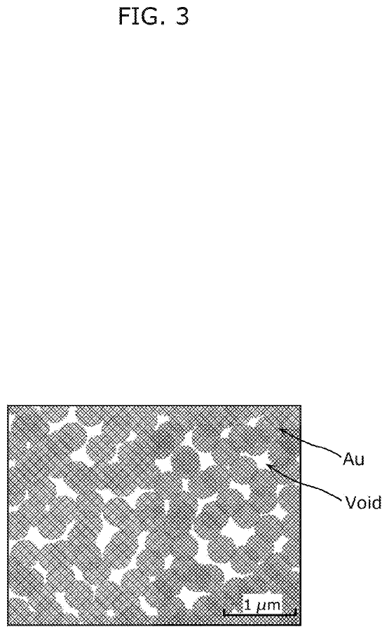

Connecting member 80 is a member that connects mounting substrate 10 and submount 20. Connecting member 80 is composed of a porous metal material. The microscopic structure of connecting member 80 will be described with reference to FIG. 3. FIG. 3 is a schematic magnified cross-sectional view of the microscopic structure of connecting member 80 according to the present embodiment. In FIG. 3, a hatched area in the solid box indicates a metal material (Au in the example illustrated in FIG. 3) and white areas in the solid box indicate voids. As illustrated in FIG. 3, connecting member 80 is composed of a porous metal material having voids each of which is at most approximately 1 μm in size. In the present embodiment, connecting member 80 is composed approximately of fine metal particles. Stated differently, connecting member 80 is an aggregation of fine metal particles sintered while partially maintaining the shape of the particles. Gaps between the fine metal particles, which are sintered while partially maintaining the shape of the particles, form voids in connecting member 80. Owing to such voids, porous connecting member 80 is achieved. Connecting member 80 is formed by, for example, heating organic solvent that includes fine metal particles with an average particle size (hereinafter simply referred to as “a particle size”) of at least 1 μm at a relatively low temperature of approximately 200 degrees Celsius. This makes it possible to sinter the fine metal particles to bond the fine metal particles together. The detailed method of forming connecting member 80 will be described later. Connecting member 80 includes, for example, at least one of Au, Ag, Cu, or Al. Such connecting member 80 can achieve the thermal conductivity of, for example, at least 150 W/(m*K). This makes it possible to efficiently conduct heat generated at semiconductor laser 30 to mounting substrate 10 via submount 20 and connecting member 80. The thermal conductivity of connecting member 80 may be greater than or equal to the thermal conductivity of submount 20. This makes it possible to more efficiently conduct, by connecting member 80, heat generated at semiconductor laser 30 to mounting substrate 10.

As illustrated in FIG. 2, connecting member 80 includes central portion 81 and peripheral portion 82. Central portion 81 is a portion sandwiched between bottom surface 20d of submount 20 and top surface 10a of mounting substrate 10, and is located approximately at the center of connecting member 80. In the present embodiment, spacer 22 is disposed occupying most of the part between central portion 81 and bottom surface 20d of submount 20. As illustrated in FIG. 1 and FIG. 2, peripheral portion 82 is a portion that continuously covers at least part of front face 20a of submount 20 and the peripheral area of an area, which corresponds to submount 20, of top surface 10a of mounting substrate 10. The peripheral area of the area, which corresponds to submount 20, of top surface 10a of mounting substrate 10 is an area located at the periphery of submount 20 in the plan view of top surface 10a of mounting substrate 10. In the present embodiment, peripheral portion 82 is disposed at the entire periphery of bottom surface 20d of submount 20. In other words, peripheral portion 82 is disposed at all of lateral faces (including front face 20a and rear face 20b) that connect upper surface 20c and bottom surface 20d of submount 20. Top surface 82a of peripheral portion 82 is straight or recessed at a cross section that intersects front face 20a of submount 20 and top surface 10a of mounting substrate 10. As used herein, the expression that top surface 82a of peripheral portion 82 is recessed means that peripheral portion 82 is in a fillet shape. Stated differently, the expression that top surface 82a of peripheral portion 82 is recessed means that top surface 82a is downwardly protruding.

With peripheral portion 82 described above, it is possible to conduct heat generated at semiconductor laser 30 and conducted by submount 20 not only via central portion 81 of connecting member 80 as indicated by the dashed arrows in FIG. 2, but also via peripheral portion 82 of connecting member 80 as indicated by the solid arrows in FIG. 2. Since it is difficult to conduct heat generated near front end face 30a of semiconductor laser 30, the amount of heat conducted to the vicinity of front face 20a of submount 20 is large. Since peripheral portion 82 continuously covers at least part of front face 20a of submount 20 and the peripheral area of an area, which corresponds to front face 20a, of top surface 10a of mounting substrate 10, the heat conducted to the vicinity of front face 20a of submount 20 can be efficiently conducted to mounting substrate 10. Therefore, with semiconductor laser light-emitting device 1, it is possible to efficiently conduct heat generated at semiconductor laser 30 to mounting substrate 10 via submount 20.

Since top surface 82a of peripheral portion 82 is straight or recessed at a cross section that intersects front face 20a of submount 20 and top surface 10a of mounting substrate 10, interference between peripheral portion 82 and a laser beam emitted from front end face 30a of semiconductor laser 30 can be reduced more than when top surface 82a is upwardly protruding (see FIG. 2). Therefore, according to semiconductor laser light-emitting device 1, it is possible to reduce loss in the propagation of a laser beam emitted from semiconductor laser 30, and this in turn makes it possible to enhance the use efficiency of laser beams.

Moreover, top surface 82a of peripheral portion 82 decreases in height with increasing distance from submount 20. In other words, top surface 82a of peripheral portion 82 gets closer to top surface 10a of mounting substrate 10 with increasing distance from submount 20. This can further reduce the interference between peripheral portion 82 and a laser beam emitted from semiconductor laser 30.

Owing to connecting member 80 including central portion 81 and peripheral portion 82, not only bottom surface 20d of submount 20 but also the lateral faces including front face 20a are connected to mounting substrate 10 by connecting member 80. Therefore, with semiconductor laser light-emitting device 1, top surface 10a of mounting substrate 10 can be more firmly connected to submount 20 than when connecting member 80 includes only central portion 81.

Semiconductor laser 30 and submount 20 are bonded to each other by, for example, AnSn solder or the like, although not shown in the figures.

### [1-2. Heat Dissipation Property]

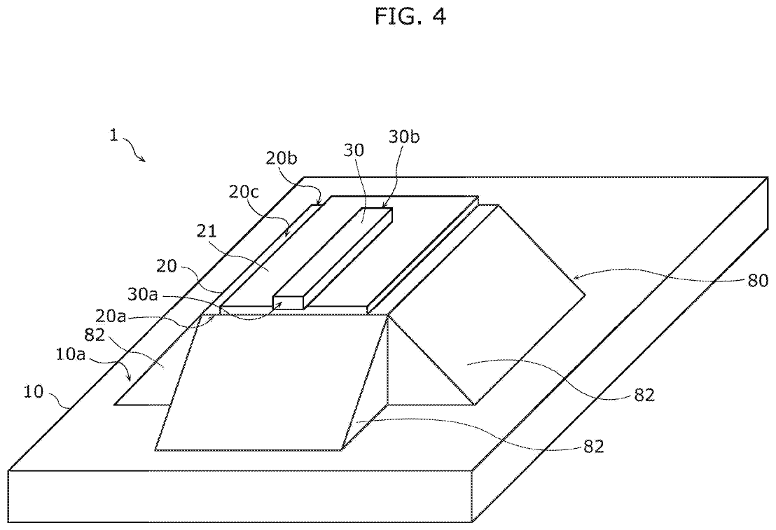

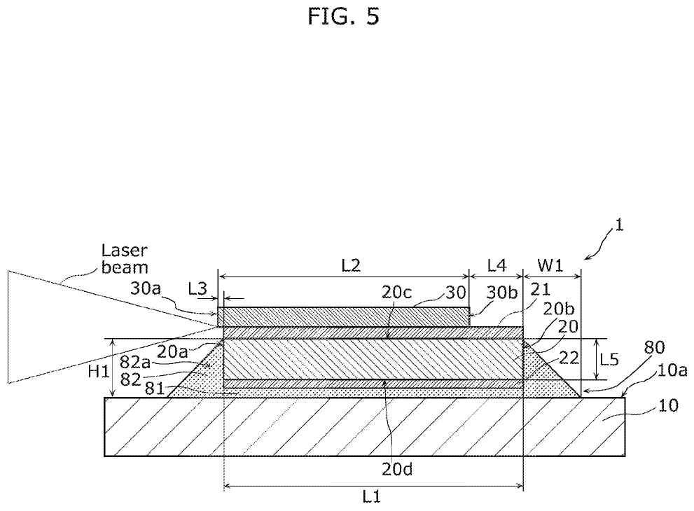

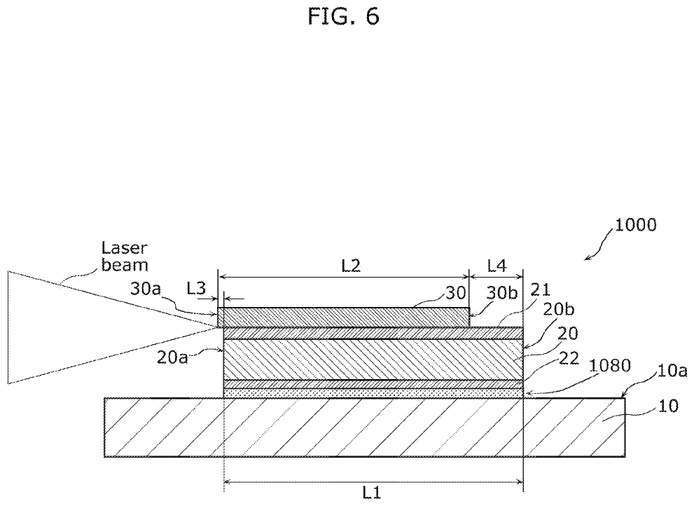

Next, the heat dissipation property of semiconductor laser light-emitting device 1 according to the present embodiment will be described in comparison with a comparative example based on a simulation result. First, the configurations of semiconductor laser light-emitting device 1 according to the present embodiment and a semiconductor laser light-emitting device according to the comparative example that are used in a simulation will be described with reference to FIG. 4 through FIG. 6. FIG. 4 and FIG. 5 are a perspective view and a cross-sectional view, respectively, of the configuration of semiconductor laser light-emitting device 1 according to the present embodiment and used in the simulation. FIG. 6 is a cross-sectional view of the configuration of semiconductor laser light-emitting device 1000 according to the comparative example and used in the simulation. FIG. 5 illustrates a cross section that passes through the optical axis of semiconductor laser light-emitting device 1 according to the present embodiment and is perpendicular to top surface 10a of mounting substrate 10. FIG. 6 illustrates a cross section that passes through the optical axis of semiconductor laser light-emitting device 1000 according to the comparative example and is perpendicular to top surface 10a of mounting substrate 10.

In the configuration of semiconductor laser light-emitting device 1 used in the present simulation, peripheral portion 82 of connecting member 80 covers all of the lateral faces of submount 20 including front face 20a and rear face 20b, as illustrated in FIG. 4. Peripheral portions 82 each cover a different one of the lateral faces of submount 20 and have the shape of a triangular prism. The triangular prism has a right triangular base and is disposed on top surface 10a of mounting substrate 10 so that the right triangular base of the triangular prism is oriented to be perpendicular to top surface 10a. In other words, the triangular prism is disposed lying on top surface 10a of mounting substrate 10.

The size of semiconductor laser light-emitting device 1 used in the present simulation will be described with reference to FIG. 5. Length L1 of submount 20 and length L2 of semiconductor laser 30 in the horizontal direction (i.e., the resonator length direction of semiconductor laser 30) in FIG. 5 are 1400 μm and 1200 μm, respectively. Protrusion amount L3 of semiconductor laser 30 from front face 20a of submount 20 is 10 μm. Distance L4 from rear end face 30b of semiconductor laser 30 to rear face 20b of sub mount 20 is 210 μm. The thickness of semiconductor laser 30 (a size in the up and down direction in FIG. 5) is 90 μm, and the size of semiconductor laser 30 in a direction perpendicular to the surface of the sheet showing FIG. 5 is 150 μm. Distance L5 from bottom surface 20d to top surface 20c of submount 20 is 200 μm. The size of submount 20 in the direction perpendicular to the surface of the sheet showing FIG. 5 is 1000 μm. Height H1 of peripheral portion 82 of connecting member 80 (the height from top surface 10a of mounting substrate and width W1 (i.e., the distance from each of the lateral faces of submount 20 to the outer end of peripheral portion 82) are each 250 μm.

Electrode 21 and spacer 22 each has a thickness of 50 μm.

In semiconductor laser light-emitting device 1 used in the present simulation, submount 20 comprises AlN and connecting member 80 comprises Au. Electrode 21 and spacer 22 each comprise Cu.

The present simulation assumes a 3A drive that supplies current of 3 A to semiconductor laser 30, and the amount of heat generated from semiconductor laser 30 per unit time is 7.4 W. The temperature of the bottom surface of mounting substrate 10 is 25 degrees Celsius.

Next, the model of semiconductor laser light-emitting device 1000 according to the comparative example and used in the present simulation will be described with reference to FIG. 6. As illustrated in FIG. 6, semiconductor laser light-emitting device 1000 according to the comparative example is different from semiconductor laser light-emitting device 1 according to the present embodiment in regard to the inclusion of connecting member 1080 instead of connecting member 80, and is same as semiconductor laser light-emitting device 1 in regard to the other aspects. Connecting member 1080 has the same configuration as central portion 81 of connecting member 80. In other words, connecting member 1080 according to the comparative example is different from connecting member 80 according to the present embodiment in regard to the non-inclusion of peripheral portion 82, and is same as connecting member 80 in regard to the other aspects.

The simulation was conducted for each of semiconductor laser light-emitting device 1 according to the present embodiment and semiconductor laser light-emitting device 1000 according to the comparative example having the configurations as described above. As a result, the highest temperature of semiconductor laser 30 was 58.9 degrees Celsius in semiconductor laser light-emitting device 1000 according to the comparative example, and was 57.7 degrees Celsius in semiconductor laser light-emitting device 1 according to the present embodiment. Semiconductor laser light-emitting device 1 according to the present embodiment, as compared to semiconductor laser light-emitting device 1000 according to the comparative example, can thus reduce the highest temperature by 1.2 degrees Celsius. The result shows that the thermal resistance between semiconductor laser 30 and mounting substrate 10 is 4.59 degrees Celsius/W in semiconductor laser light-emitting device 1000 according to the comparative example and is 4.42 degrees Celsius/W in semiconductor laser light-emitting device 1 according to the present embodiment. With semiconductor laser light-emitting device 1 according to the present embodiment, it is thus possible to reduce the thermal resistance between semiconductor laser 30 and mounting substrate 10 by 0.17 degrees Celsius/W.

As described above, the only difference between semiconductor laser light-emitting device 1 according to the present embodiment and semiconductor laser light-emitting device 1000 according to the comparative example is the presence or absence of peripheral portion 82 of connecting member 80. The provision of peripheral portion 82 can therefore reduce the thermal resistance between semiconductor laser 30 and mounting substrate 10 by 0.17 degrees Celsius/W. With semiconductor laser light-emitting device 1 according to the present embodiment, it is possible to efficiently conduct heat generated at semiconductor laser 30 to mounting substrate 10 via submount 20.

### [1-3. Shape of Peripheral Portion]

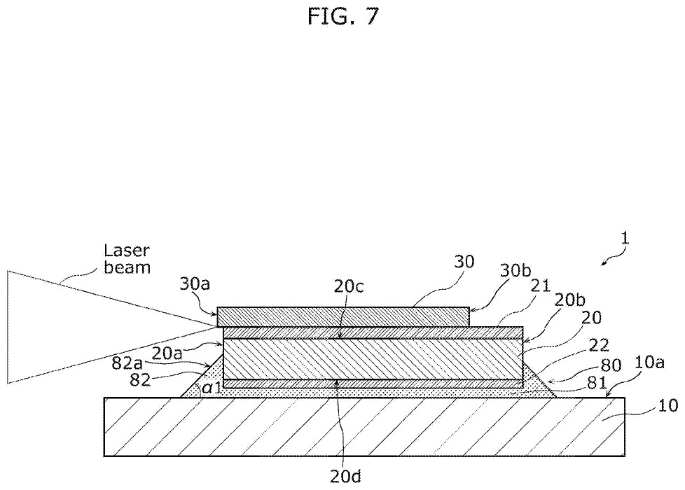

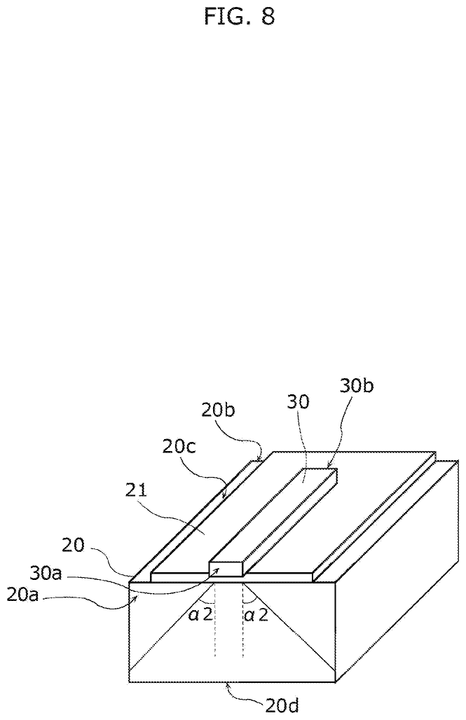

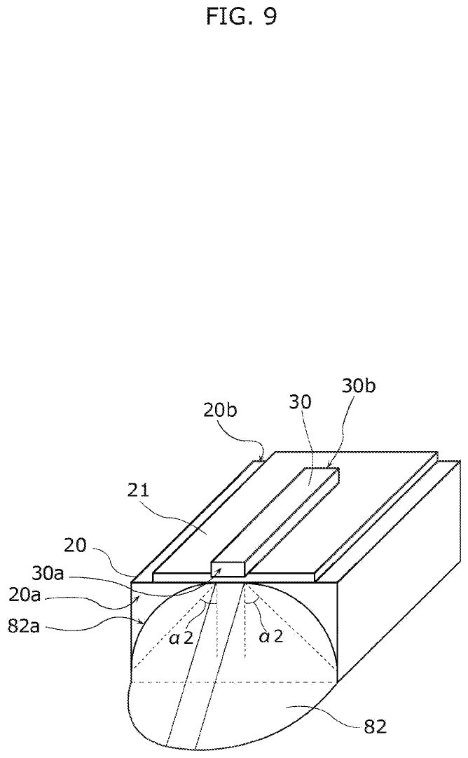

Next, the shape of peripheral portion 82 of connecting member according to the present embodiment will be described with reference to FIG. 7 through FIG. 9. FIG. 7 is a schematic cross-sectional view of the shape of peripheral portion 82 of connecting member 80 in semiconductor laser light-emitting device 1 according to the present embodiment. FIG. 8 is a schematic perspective view of the heat conduction area in a heat diffusion model for diffusing heat from semiconductor laser 30 to submount 20. FIG. 9 is a schematic perspective view illustrating one example of the shape of peripheral portion 82 according to the present embodiment.

As illustrated in FIG. 7, al 90 degrees) denotes the angle between top surface 82a of peripheral portion 82 according to the present embodiment and top surface 10a of mounting substrate 10. The angle between front face 20a of submount 20 and a main path along which heat is conducted from front face 20a of submount 20 to mounting substrate 10 via peripheral portion 82 (see the solid arrows in FIG. 2) is approximately 45 degrees at maximum. Since a general heat diffusion model assumes that heat diffuses at the angle of 45 degrees, angle α1 between top surface 82a of peripheral portion 82 and top surface 10a of mounting substrate 10 may be 45 degrees or less to secure the main path along which heat is conducted from front face 20a of submount 20 to mounting substrate 10 via peripheral portion 82.

Since it is near front end face 30a that the temperature is highest in semiconductor laser 30, heat generated at semiconductor laser 30 can be efficiently conducted to mounting substrate 10 via front face 20a of submount 20 and peripheral portion 82 by disposing peripheral portion 82 of connecting member 80 on front face 20a, of submount 20, that is disposed near front end face 30a.

The distance from bottom surface 20d of submount 20 to the position at which at least part of top surface 82a of peripheral portion 82 contacts front face 20a of submount 20 may be from 40% to 100%, inclusive, of the distance from bottom surface 20d to top surface 20c of submount 20 (distance L5 shown in FIG. 5). This makes it possible to sufficiently secure the area of contact between peripheral portion 82 and front face 20a of submount 20, making it possible to efficiently conduct heat generated at semiconductor laser 30 to mounting substrate 10 via submount 20 and peripheral portion 82.

The distance from bottom surface 20d of submount 20 to the position at which top surface 82a of peripheral portion 82 contacts front face 20a of submount 20 may be greater than the distance from bottom surface 20d of submount 20 to the position at which top surface 82a of peripheral portion 82 contacts rear face 20b of submount 20. Since the amount of heat conducted to the vicinity of front face 20a of submount 20 is large, as described above, heat on the front face 20a side that leads to property degradation can be efficiently conducted to mounting substrate 10 if the height of top surface 82a of peripheral portion 82 is greater at front face 20a than at rear face 20b of submount 20.

In the general heat diffusion model, angle α2 between (i) the boundary of the heat conduction area in which heat diffuses from semiconductor laser 30 to mounting substrate 10 and (ii) a direction directly downward from semiconductor laser 30 is 45 degrees when viewed from front face 20a of submount 20, as illustrated in FIG. 8, and the amount of heat to be conducted is largest particularly below the optical axis of semiconductor laser 30. Therefore, the distance from bottom surface 20d of submount 20 to the position at which top surface 82a of peripheral portion 82 contacts front face 20a of submount 20 may be greatest below the optical axis of semiconductor laser 30. This makes it possible to dispose peripheral portion 82 in an area, of front face 20a of submount 20, through which much heat is conducted, making it possible to enhance the heat dissipation property of semiconductor laser light-emitting device 1.

As illustrated in FIG. 9, peripheral portion 82 of connecting member 80 may cover an area, of front face 20a of submount 20, including the heat conduction area as defined in the heat diffusion model. In other words, peripheral portion 82 may cover a region that includes a straight line that forms angle α2 of 45 degrees or less with the direction downward from semiconductor laser 30, among straight lines that extend in the in-plane direction of front face 20a from the part at which semiconductor laser 30 contacts front face 20a. Of front face 20a of submount 20, peripheral portion 82 covers the heat conduction region and its periphery in the example illustrated in FIG. 9. According to the example illustrated in FIG. 9, it is possible to reduce the volume of connecting member 80 more than when periphery portion 82 covers the entire front face 20a, while inhibiting a reduction in the heat dissipation property of semiconductor laser light-emitting device 1. This makes it possible to reduce the weight and cost of semiconductor laser light-emitting device 1.

### [1-4. Manufacturing Methods]

Next, methods for manufacturing semiconductor laser light-emitting device 1 according to the present embodiment will be described.

### [1-4-1. First Manufacturing Method]

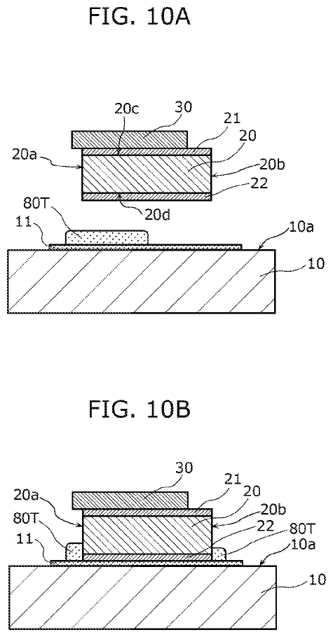

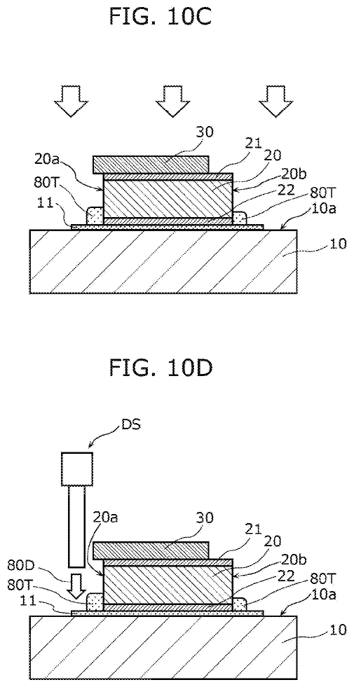

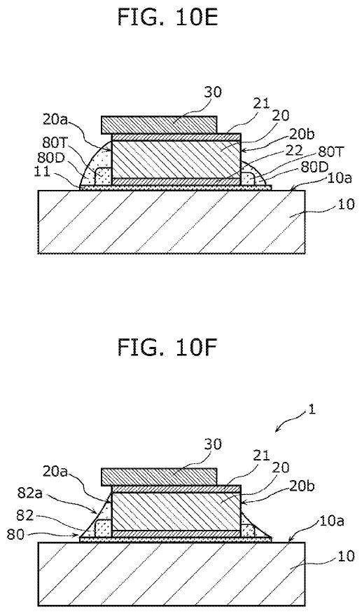

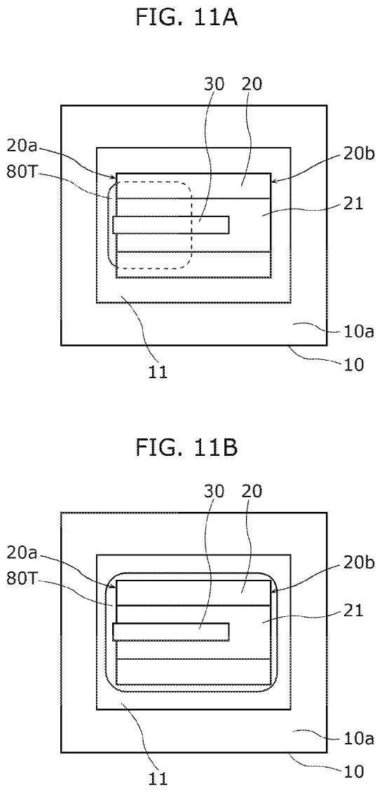

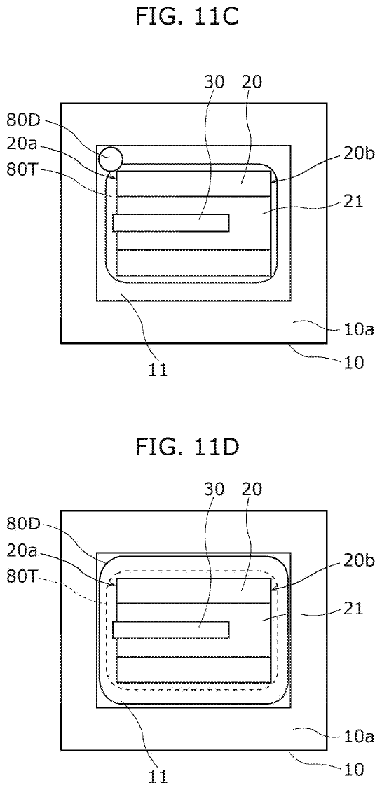

First, a first manufacturing method that is one example of a method for manufacturing semiconductor laser light-emitting device 1 will be described with reference to FIG. 10A through FIG. 10F and FIG. 11A through FIG. 11D. FIG. 10A through FIG. 10F are each a schematic cross-sectional view illustrating a different one of processes in the first manufacturing method of semiconductor laser light-emitting device 1 according to the present embodiment. FIG. 11A through FIG. 11D are each a schematic plan view illustrating a different one of processes in the first manufacturing method of semiconductor laser light-emitting device 1 according to the present embodiment. FIG. 11A through FIG. 11D each illustrate a plan view when top surface 10a of mounting substrate 10 is viewed from top.

As illustrated in FIG. 10A, submount 20 is prepared and semiconductor laser 30 is provided on top surface 20c of submount 20 (providing of a semiconductor laser). In the present embodiment, electrode 21 and spacer 22 are formed on top surface 20c and bottom surface 20d of submount 20, respectively, and semiconductor laser 30 is provided on electrode 21. As illustrated in FIG. 10A and FIG. 11A, mounting substrate 10 is prepared and first metal particles having a first particle size are applied to top surface 10a of mounting substrate 10 (applying of first metal particles). In the present embodiment, first metal paste 80T including the first metal particles is applied to top surface 10a of mounting substrate 10. In the present embodiment, underlying metal 11 is formed on top surface 10a of mounting substrate 10 and first metal paste 80T is applied to underlying metal 11. Underlying metal 11 is a metal layer that is disposed between connecting member 80 and top surface 10a of mounting substrate 10 and assists bonding between connecting member 80 and top surface 10a of mounting substrate 10. Underlying metal 11 includes, for example, the same metal as the metal included in connecting member 80. This makes it easier for connecting member 80 and underlying metal 11 to be bonded to each other. In the present embodiment, underlying metal 11 includes Au. Weak Ar plasma processing or UV ozone processing may be performed on each of the lateral faces of submount 20 in advance so that the wetness of the lateral face of submount 20 may be enhanced beforehand for organic solvent which is described later. This makes it easier for the shape of the paste attached to each of the lateral faces of submount 20 to be straight or recessed.

First metal paste 80T is a material to be sintered to form part of connecting member 80. First metal paste 80T includes first metal particles having a first particle size. First metal paste 80T is a paste that includes the first metal particles, solvent, and surfactant. The first particle size of the first metal particles is 1 μm or less. In the present embodiment, the first metal particles comprise Au. The solvent included in first metal paste 80T is, for example, organic solvent such as ester alcohol (2,2,4-trimethyl-3-hydroxypenta isobuterate: C₁₂H₂₄O₃), terpineol, pine oil, butyl carbitol acetate, butyl carbitol, carbitol, etc. The surfactant is, for example, alkylamine (CH₃(CH₂)ₙNH₂), alkylamine carboxylate, carboxylic acid amide, ester amine, organic titanium compound, sulfocarboxylic acid natrium, etc. Such a first metal paste can be applied using, for example, a dispenser method.

First metal paste 80T is applied to at least an area below front face 20a of submount 20, as illustrated in FIG. 10A and FIG. 11A.

Subsequently, submount 20 is disposed on first metal paste 80T, as illustrated in FIG. 10B and FIG. 11B (disposing of a submount). By thus disposing submount 20 on first metal paste 80T, the first metal particles are disposed so as to contact front face 20a of submount 20. In the present embodiment, submount 20 is pressed against top surface 10a of mounting substrate 10. With this, first metal paste 80T is spread and adheres to front face 20a of submount 20. In the present embodiment, first metal paste 80T adheres also to lateral faces (including rear face 20b) of submount 20 other than front face 20a.

Subsequently, first metal paste 80T is sintered (sintering of the first metal particles). In other words, first metal paste 80T is heated to sinter the first metal particles to fuse with the adjacent first metal particles, as well as to evaporate the solvent. As a result, of first metal paste 80T, approximately only first metal particles 80L remain and a porous metal is formed. Since the first particle size of the first metal particles is fpm or less, the first metal particles can be sintered by heating the first metal particles at a relatively low temperature of approximately 200 degrees Celsius owing to size effect.

Subsequently, organic substance is removed from the surface of submount 20. In the present embodiment, weak Ar plasma processing or UV ozone processing is performed on the surface of submount 20 in the direction indicated by the arrows, as illustrated in FIG. 10C. This makes it possible to enhance the wetness of the surface of submount 20. It should be noted that the process of removing organic substance is not an essential process in the manufacturing method of semiconductor laser light-emitting device 1 according to the present embodiment. In other words, this process may be omitted.

Subsequently, second metal particles having a second particle size are applied to the first metal particles disposed between front face 20a of submount 20 and top surface 10a of mounting substrate 10, as illustrated in FIG. 10D and FIG. 11C (applying of second metal particles). In the present embodiment, second metal paste 80D including the second metal particles is applied to the first metal particles. Second metal paste 80D is a paste that includes the second metal particles, solvent, and surfactant. The second size of the second metal particles is 1 μm or less. In the present embodiment, the second metal particles comprise Au. The solvent and the surfactant included in second metal paste 80D respectively comprise the same material as the solvent and the surfactant included in first metal paste 80T. The concentration of the metal included in first metal paste 80T is higher than the concentration of the metal included in second metal paste 80D. Since the metal concentration is thus lower in second metal paste 80D than in first metal paste 80T, second metal paste 80D has better wetness for front face 20a of submount 20 than first metal paste 80T. Therefore, just by applying second metal paste 80D to a single area on the first metal particles using, for instance, dispenser DS, as illustrated in FIG. 10D, second metal paste 80D spreads over, for instance, front face 20a of submount 20, as illustrated in FIG. 10E and FIG. 11D. Moreover, by removing organic substance from the surface of submount 20 in the above-mentioned organic removal process, it is much easier for second metal paste 80D to spread over, for instance, front face 20a of submount 20.

Subsequently, second metal paste 80D is sintered (sintering of the second metal particles). In other words, second metal paste 80D is heated to sinter the second metal particles to fuse with the adjacent second metal particles, as well as to evaporate solvent. Since the second particle size of the second metal particles is 1 μm or less, the second metal particles can be sintered by heating the second metal particles at a relatively low temperature of approximately 200 degrees Celsius. By thus sintering second metal paste 80D, connecting member 80 including the first metal particles and the second metal particles is formed. When sintering second metal paste 80D, the solvent evaporates so that second metal paste 80D forms a fillet shape, as illustrated in FIG. 10F. This allows the shape of top surface 82a of peripheral portion 82 of connecting member 80 at a cross section that intersects front face 20a of submount 20 and top surface 10a of mounting substrate 10 to be straight or recessed.

As described above, the method for manufacturing semiconductor laser light-emitting device 1 according to the present embodiment includes: providing semiconductor laser 30 on top surface 20c of submount 20; applying first metal particles having a first particle size to the top surface of mounting substrate 10; disposing submount 20 on the first metal particles so as to contact front face 20a of submount 20, where front face 20a is a face on the light emission side of semiconductor laser 30; and applying second metal particles having a second particle size to the first metal particles.

The manufacturing method as described above allows the approximate shape of top surface 82a of peripheral portion 82 of connecting member 80 at a cross section that intersects front face 20a of submount 20 and top surface 10a of mounting substrate 10 to be straight or recessed.

In the above-described first manufacturing method, first metal paste 80T and second metal paste 80D are applied, but the manufacturing method of semiconductor laser light-emitting device 1 according to the present embodiment is not limited to this. For example, second metal paste 80D may be sintered while submount 20 is disposed on underlying metal 11 after only second metal paste 80D has been applied to underlying metal 11. Such a manufacturing method can also form connecting member 80 according to the present embodiment.

In the first manufacturing method described above, second metal paste 80D is applied after first metal paste 80T has been sintered, but second metal paste 80D may be applied before first metal paste 80T is sintered. For example, second metal paste 80D may be applied while the shape of first metal paste 80T is approximately solid after at least part of the solvent in first metal paste 80T has evaporated.

### [1-4-2. Second Manufacturing Method]

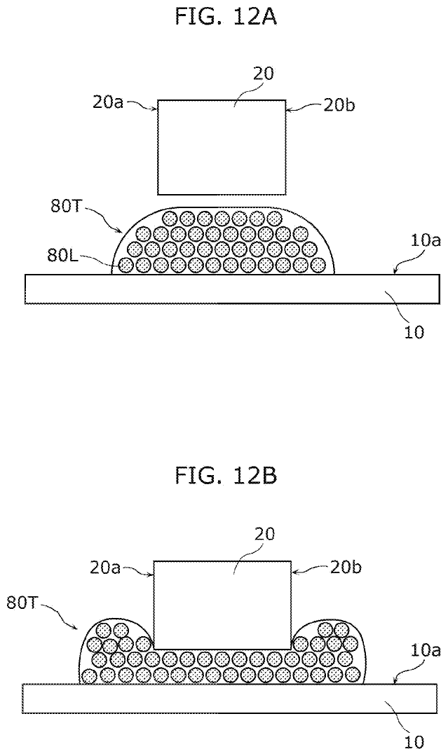

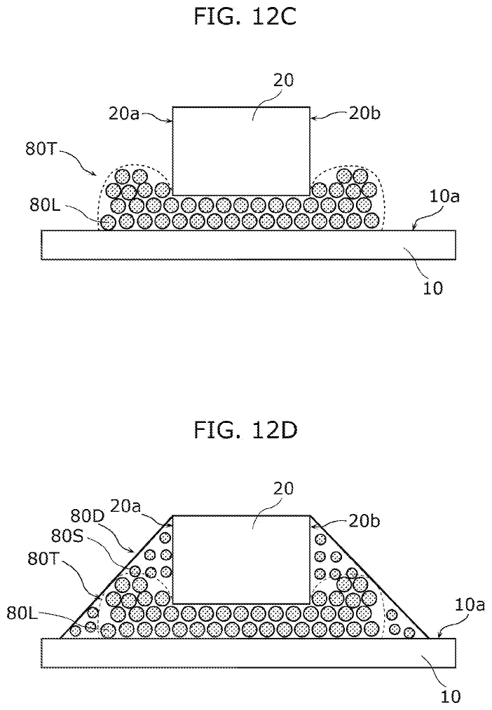

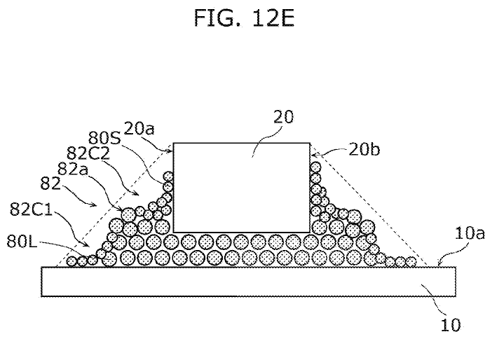

Next, a second manufacturing method that is another example of the manufacturing method of semiconductor laser light-emitting device 1 according to the present embodiment will be described. The second manufacturing method differs from the first manufacturing method in regard mainly to the composition of the second metal paste. Hereinafter, the second manufacturing method will be described with reference to FIG. 12A through FIG. 12E, focusing on the difference from the first manufacturing method. FIG. 12A through FIG. 12E are each a cross-sectional view illustrating a different one of processes in the second manufacturing method of semiconductor laser light-emitting device 1 according to the present embodiment.

As illustrated in FIG. 12A, first, submount 20 is prepared, as is the case of the first manufacturing method. In FIG. 12A through FIG. 12E, semiconductor laser 30, electrode 21, spacer 22, and underlying metal 11 are omitted to prevent drawings from being complexed. Semiconductor laser 30 is provided on top surface 20c of submount 20 also in the second manufacturing method, as is the case of the first manufacturing method. In addition, mounting substrate 10 is prepared and first metal paste 80T is applied to mounting substrate 10. First metal paste 80T, like first metal paste 80T used in the first manufacturing method, is a paste that includes first metal particles 80L having the first particle size, solvent, and surfactant.

Subsequently, submount 20 is disposed on first metal paste 80T, as illustrated in FIG. 12B. By thus disposing submount 20 on first metal paste 80T, first metal particles 80L are disposed between front face 20a of submount 20 and top surface 10a of mounting substrate 10.

Subsequently, first metal paste 80T is sintered. In other words, first metal paste 80T is heated to sinter first metal particles 80L to fuse with adjacent first metal particles 80L, as well as to evaporate the solvent. As a result, of first metal paste 80T, approximately only first metal particles 80L remain, as illustrated in FIG. 12C. A cross section of sintered first metal paste 80T (i.e., an aggregation of first metal particles 80L) is upwardly protruding, as illustrated in FIG. 12C. After sintering first metal paste 80T, organic substance may be removed, as is the case of the first manufacturing method.

Subsequently, second metal paste 80D including second metal particles 80S having a second particle size is applied to first metal particles 80L disposed between front face 20a of submount 20 and top surface 10a of mounting substrate 10. Second metal paste 80D is a paste that includes second metal particles 80S, solvent, and surfactant. The second particle size of the second metal particles is 1 μm or less. In the second manufacturing method, the first particle size is greater than the second particle size. The second metal particles comprise Au. The solvent and the surfactant included in second metal paste 80D respectively comprise the same material as the solvent and the surfactant included in first metal paste 80T.

As is the case of the first manufacturing method, since the concentration of the metal included in first metal paste 80T is higher than the concentration of the metal included in second metal paste 80D, second metal paste 80D is spread over, for instance, front face 20a of submount 20 and covers first metal particles 80L, as illustrated in FIG. 12D. Since the second particle size of second metal particles 80S is 1 μm or less and is smaller than the first particle size of first metal particles 80L, a density gradient caused by the gravity of second metal particles 80S in second metal paste 80D can be reduced. In other words, the density of second metal particles 80S in second metal paste 80D can be equalized.

Subsequently, second metal paste 80D is sintered. With this, of second metal paste 80D, approximately only second metal particles 80S remain. As a result, second metal particles 80S are sintered and bonded to each of the lateral faces of submount 20 including front face 20a and rear face 20b, first metal particles 80L, and top surface 10a of mounting substrate 10. An aggregation of first metal particles 80L and second metal particles 80S thus formed is connecting member 80. Peripheral portion 82 of connecting member 80 is also formed between top surface 10a of mounting substrate 10 and the lateral faces of submount 20 including front face 20a and rear face 20b. In the second manufacturing method, of top surface 82a of peripheral portion 82, first recessed portion 82C1 is formed between top surface 10a of mounting substrate 10 and a protruding portion formed by the aggregation of first metal particles 80L, and second recessed portion 82C2 is formed between the protruding portion, which is formed by the aggregation of first metal particles 80L, and the lateral faces of submount 20 including front face 20a and rear face 20b, as illustrated in FIG. 12E. Stated differently, top surface 82a of peripheral portion 82 includes first recessed portion 82C1 and second recessed portion 82C2 at a cross section that intersects front face 20a of submount 20 and top surface 10a of mounting substrate 10. At least part of first recessed portion 82C1 and part of second recessed portion 82C2 are covered by second metal particles 80S.

This shape can be regarded as approximately straight or recessed.

As described above, according to the second manufacturing method, since second metal paste 80D including second metal particles 80S having the second particle size smaller than the first particle size of first metal particles 80L is used, a density gradient caused by the gravity of second metal particles 80S in second metal paste 80D can be reduced. It is therefore possible to bond second metal particles 80S even to the upper part of each of the lateral faces of submount 20. This makes it possible to dispose peripheral portion 82 of connecting member 80 at a location relatively close to semiconductor laser 30 that is the source of generated heat, making it possible to efficiently conduct heat generated at semiconductor laser 30 to mounting substrate 10 via submount 20 and peripheral portion 82 of connecting member 80.

According to the second manufacturing method, peripheral portion 82 of connecting member 80 includes a first region formed mainly of first metal particles 80L and a second region formed mainly of second metal particles 80S. Since the second particle size of second metal particles 80S is smaller than the first particle size of first metal particles 80L, the average size of voids in the second region is smaller than the average size of voids in the first region. Thus, connecting member 80 formed using the second manufacturing method has a characteristic structure.

### [1-4-3. Third Manufacturing Method]

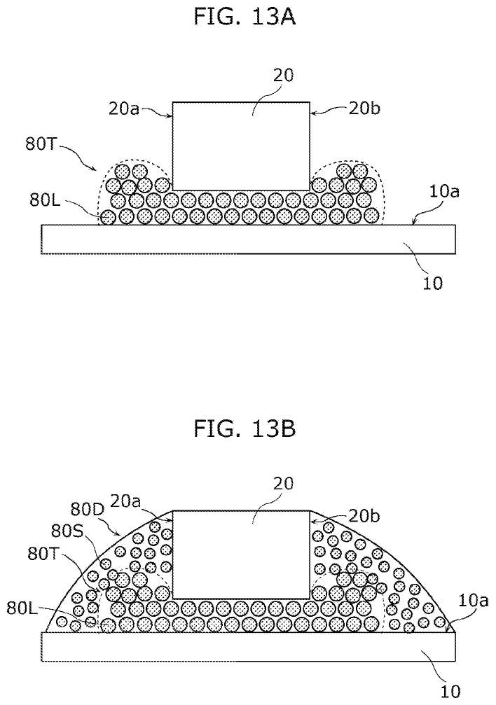

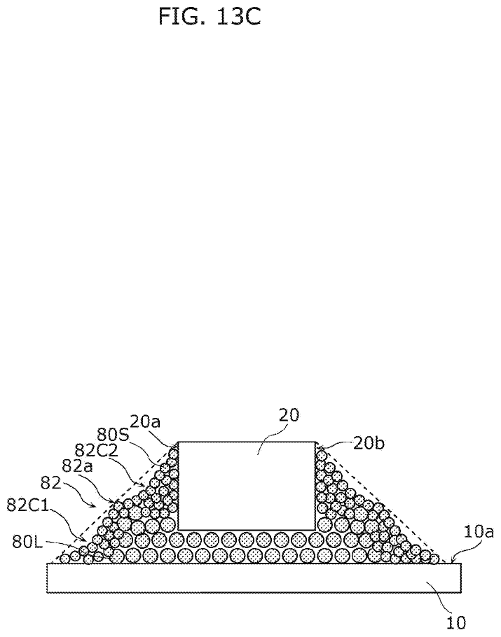

Next, a third manufacturing method that is yet another example of the manufacturing method of semiconductor laser light-emitting device 1 according to the present embodiment will be described. The third manufacturing method differs from the second manufacturing method in regard mainly to the application mode of second metal paste 80D. Hereinafter, the third manufacturing method will be described with reference to FIG. 13A through FIG. 13C, focusing on the difference from the second manufacturing method. FIG. 13A through FIG. 13C are each a schematic cross-sectional view illustrating a different one of processes in the third manufacturing method of semiconductor laser light-emitting device 1 according to the present embodiment.

The processes until first metal paste 80T is sintered are same between the third manufacturing method and the second manufacturing method. Of first metal paste 80T, approximately only first metal particles 80L remain after sintering first metal paste 80T, as illustrated in FIG. 13A. It should be noted that also in FIG. 13A through FIG. 13C, the illustration of semiconductor laser 30, electrode 21, spacer 22, and underlying metal 11 is omitted, as is the case of FIG. 12A through FIG. 12E.

Subsequently, second metal paste 80D including second metal particles 80S having the second particle size is applied to first metal particles 80L disposed between front face 20a of submount 20 and top surface 10a of mounting substrate 10. Second metal paste 80D has the same composition as second metal paste 80D used in the second manufacturing method. In the third manufacturing method, second metal paste 80D is applied in greater amount compared to the second manufacturing method so that second metal particles 80S are disposed on the entire top surface of the aggregation of first metal particles 80L, as illustrated in FIG. 13B. This makes the surface shape of second metal paste 80D protruding, utilizing surface tension.

Subsequently, second metal paste 80D is sintered. With this, of second metal paste 80D, approximately only second metal particles 80S remain. As a result, connecting member 80 is formed and first recessed portion 82C1 and second recessed portion 82C2 are formed in peripheral portion 82 of connecting member 80, as is the case of the second manufacturing method. In the third manufacturing method, the entire top surface of peripheral portion 82 is covered by second metal particles 80S. In addition, the volume of the metal paste decreases as the solvent evaporates, and the surface of peripheral portion 82 that eventually remained can be made approximately straight in the cross-sectional view of peripheral portion 82. Connecting member 80 with an approximately straight surface has higher heat dissipation than connecting member 80 of the same volume and with a recessed surface.

As described above, the third manufacturing method produces the same advantageous effects as the second manufacturing method. Peripheral portion 82 of connecting member 80 formed using the third manufacturing method also includes a first region formed mainly of first metal particles 80L and a second region formed mainly of second metal particles 80S.

### [1-5. Microscopic Structure of Connecting Member and Method of Measuring the Microscopic Structure]

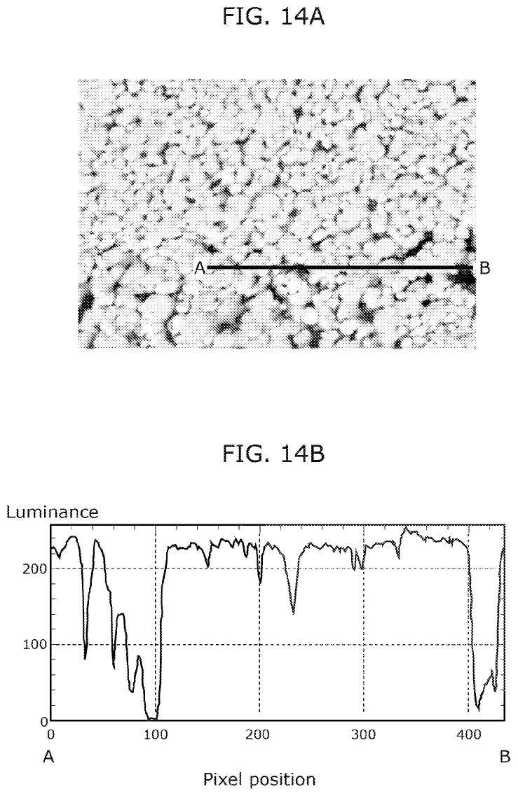

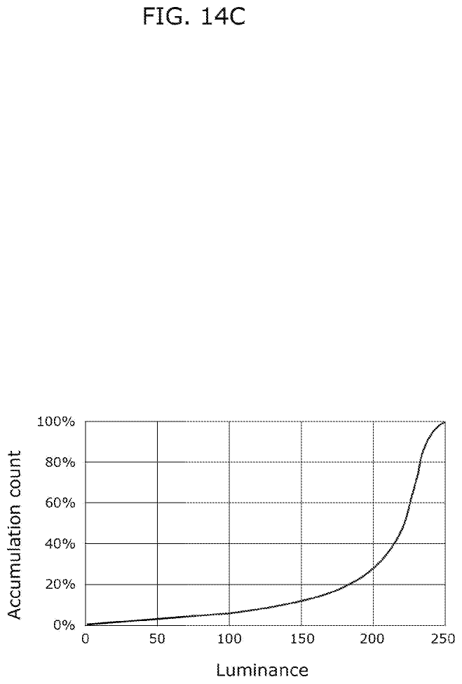

Next, the microscopic structure of connecting member 80 according to the present embodiment and a method of measuring the microscopic structure will be described with reference to FIG. 14A and FIG. 14B. FIG. 14A is one example of an electron microscope photo of a cross section of connecting member 80 according to the present embodiment. FIG. 14B is a graph showing the luminance distribution of an image taken at line A-B of the electron microscope photo illustrated in FIG. 14A. FIG. 14C is the accumulation histogram of the luminance of the image of the entire electron microscope photo illustrated in FIG. 14A.

In FIG. 14A, black areas indicate areas in which voids are located and white areas indicate areas other than the voids (mainly metal). FIG. 14B illustrates a graph presenting the luminance of each pixel of an image taken at line A-B (5 μm in length) of the image illustrated in FIG. 14A using 256 levels, to measure the proportion of voids (hereinafter referred to as “void ratio”) in a cross section of connecting member 80 in the image illustrated in FIG. 14A. In FIG. 14B, an area with a luminance of 200 or less can be determined as an area in which a void is located, for example. As illustrated in FIG. 14C, a void ratio can be calculated by obtaining the number of pixels per luminance using an accumulation histogram. The count of pixels each with a luminance of 200 or less is 28% in the image illustrated in FIG. 14A. Thus, the void ratio of connecting member 80 according to the present embodiment is less than 30%. The thermal conductivity of connecting member 80 can be increased by reducing the void ratio of connecting member 80 to less than 30%. Therefore, heat generated at semiconductor laser 30 can be efficiently conducted to mounting substrate 10 via submount 20 and connecting member 80.

The atomic ratio of the metal in the areas other than the voids in connecting member 80 can be measured using, for example, energy dispersive X-ray spectroscopy (EDX). When using the energy dispersive X-ray spectroscopy, property X-rays, which are generated by irradiating a cross section of connecting member 80 with an electron beam, are detected, and composition analysis is performed through spectroscopy. In the present embodiment, the atomic ratio of the metal in the areas other than the voids at a cross section of connecting member 80 is from 95 atomic % to 99.9 atomic %, inclusive. By thus increasing the atomic ratio of the metal, the thermal conductivity of connecting member 80 can be increased. Therefore, heat generated at semiconductor laser 30 can be efficiently conducted to mounting substrate 10 via submount 20 and connecting member 80.

### Embodiment 2

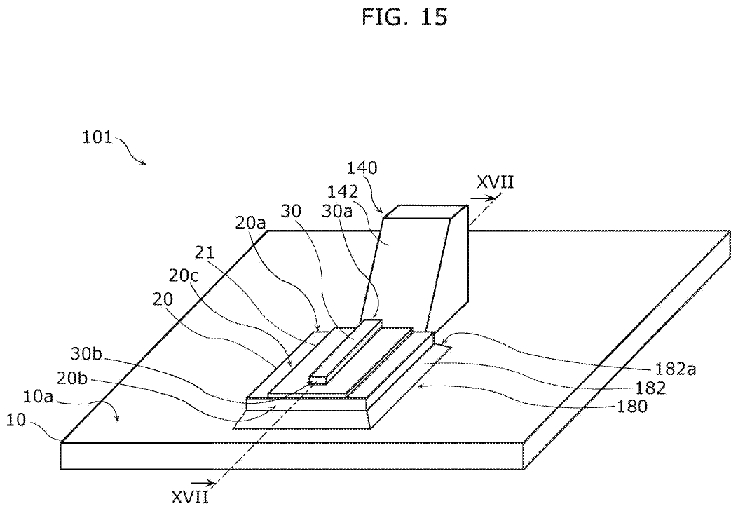

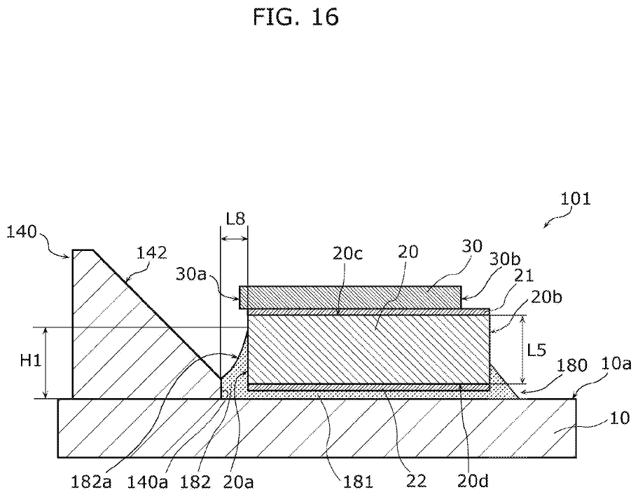

A semiconductor laser light-emitting device according to Embodiment 2 will be described. The semiconductor laser light-emitting device according to the present embodiment differs from semiconductor laser light-emitting device 1 according to Embodiment 1 in regard mainly to the inclusion of a mirror. Hereinafter, the semiconductor laser light-emitting device according to the present embodiment will be described with reference to FIG. 15 and FIG. 16, focusing on the difference from semiconductor laser light-emitting device 1 according to Embodiment 1.

FIG. 15 is a schematic perspective view of semiconductor laser light-emitting device 101 according to the present embodiment. FIG. 16 is a schematic cross-sectional view of semiconductor laser light-emitting device 101. FIG. 16 illustrates the cross section taken at line XVII-XVII in FIG. 15.

As illustrated in FIG. 15 and FIG. 16, semiconductor laser light-emitting device 101 includes mounting substrate 10, submount 20, connecting member 180, semiconductor laser 30, and mirror 140. In the present embodiment, semiconductor laser light-emitting device 101 also includes electrode 21 and spacer 22, as illustrated in FIG. 16.

Mirror 140 is an optical element that is disposed above mounting substrate 10 and facing front face 20a of submount 20, and reflects emission light from semiconductor laser 30. Mirror 140 includes reflective surface 142 that reflects emission light from semiconductor laser 30. In the present embodiment, reflective surface 142 is inclined by 45 degrees relative to the optical axis of emission light from semiconductor laser 30, and reflects the emission light in a direction perpendicular to top surface 10a of mounting substrate 10. With this, the emission light reflected by reflective surface 142 propagates in a direction away from mounting substrate 10 (i.e., upward in FIG. 16).

Mirror 140 is mounted on top surface 10a of mounting substrate 10. Mirror 140 is bonded to top surface 10a of mounting substrate 10 by connecting member 180. Distance L8 from end portion 140a of mirror 140, which faces front face 20a of submount 20, to front face 20a of submount 20 is smaller than distance L5 from bottom surface 20d to top surface 20c of submount 20 (see FIG. 16). By thus disposing mirror 140 in the vicinity of front face 20a of submount 20, that is, in the vicinity of front end face 30a of semiconductor laser 30, the spot size of emission light from semiconductor laser 30 on reflective surface 142 can be reduced. It is therefore possible to reduce the size of reflective surface 142, making it possible to reduce the size of mirror 140. Moreover, by disposing mirror 140 in the vicinity of front end face 30a of semiconductor laser 30, mounting substrate 10, and the like is irradiated with emission light from semiconductor laser 30 and light loss can be inhibited.

Connecting member 180 is a member that connects mounting substrate 10 and submount 20. Connecting member 180 is composed of the same porous metal material as the porous metal material composing connecting member 80 according to Embodiment 1. In the present embodiment, connecting member 180 includes central portion 181 and peripheral portion 182, as illustrated in FIG. 16. Central portion 181 is a portion sandwiched by bottom surface 20d of submount 20 and top surface 10a of mounting substrate 10 and is located approximately at the center of connecting member 180.

In the present embodiment, spacer 22 is disposed occupying most of the part between central portion 181 and bottom surface 20d of submount 20. Peripheral portion 182 is a portion that continuously covers at least part of front face 20a of submount 20, the peripheral area of an area, which corresponds to submount 20, of top surface 10a of mounting substrate 10, and end portion 140a, which faces front face 20a of submount 20, of mirror 140. Top surface 182a of peripheral portion 182 is straight or recessed at a cross section that intersects front face 20a of submount 20, top surface 10a of mounting substrate 10, and mirror 140.

Also in the present embodiment, the temperature of semiconductor laser 30 is highest near front end face 30a. Therefore, peripheral portion 182 of connecting member 180 is disposed at front face 20a, of submount 20, which is disposed near front end face 30a so that heat generated at semiconductor laser 30 can be efficiently conducted to mounting substrate 10 via front face 20a of submount 20 and peripheral portion 182. Since top surface 182a of peripheral portion 182 is straight or recessed at a cross section that intersects front face 20a of submount 20, top surface 10a of mounting substrate 10, and mirror 140, interference between peripheral portion 182 and a laser beam emitted from front end face 30a of semiconductor laser 30 can be reduced more than when top surface 182a is upwardly protruding.

Also in the present embodiment, top surface 182a of peripheral portion 182 decreases in height with increasing distance from submount 20, as is the case in Embodiment 1. In other words, top surface 182a of peripheral portion 182 gets closer to top surface 10a of mounting substrate 10 with increasing distance from submount 20. This makes it possible to further reduce interference between peripheral portion 182 and a laser beam emitted from semiconductor laser 30.

Also in the present embodiment, the distance from bottom surface 20d of submount 20 to the position at which at least part of top surface 182a of peripheral portion 182 contacts front face 20a of submount 20 may be from 40% to 100%, inclusive, of distance L5 from bottom surface 20d to top surface 20c of submount 20, as is the case in Embodiment 1. Since this makes it possible to sufficiently secure the area of contact between peripheral portion 182 and front face 20a of submount 20, heat generated at semiconductor laser 30 can be efficiently conducted to mounting substrate 10 via submount 20 and peripheral portion 182.

### Other Variations

The semiconductor laser light-emitting device according to the present disclosure has been described based on embodiments, but the present disclosure is not limited to the embodiments.

For example, electrode 21 and spacer 22 are not essential elements of the semiconductor laser light-emitting device according to the present disclosure. In other words, the semiconductor laser light-emitting device according to the present disclosure needs to include neither electrode 21 nor spacer 22.

In each of the embodiments, semiconductor laser 30 protrudes from front face 20a of submount 20, but is not limited to this. Semiconductor laser 30 need not protrude from front face 20a of submount 20. For example, the location of front end face 30a of semiconductor laser 30 in the optical axis direction may be same as the location of front face 20a of submount 20 or recessed from the location of front face 20a of submount 20.

Various modifications of the above embodiments and variations that may be conceived by persons skilled in the art, as well as embodiments resulting from arbitrary combinations of elements and functions from different embodiments and variations that do not depart from the essence of the present disclosure are also included in the present disclosure.

### INDUSTRIAL APPLICABILITY

The semiconductor laser light-emitting device according to the present disclosure is useful as a light source for products in various fields, e.g., image display devices such as projectors, vehicle components such as in-vehicle headlights, lighting equipment such as spotlights, or industrial equipment such as laser processing devices, and is particularly useful as a light source for devices that require relatively high light output.

1. A semiconductor laser light-emitting device comprising:
a mounting base;
a submount disposed above the mounting base;
a connecting member that connects the mounting base and the submount and is composed of a porous metal material; and
a semiconductor laser disposed above the submount, wherein
the submount includes a front face that is a face on a light emission side of the semiconductor laser,
the connecting member includes a peripheral portion that continuously covers at least part of the front face of the submount and a peripheral area of a first area of a top surface of the mounting base, the first area corresponding to the submount, and
a top surface of the peripheral portion is straight or recessed at a cross section that intersects the front face of the submount and the top surface of the mounting base.

2. The semiconductor laser light-emitting device according to claim 1, wherein
an angle between the top surface of the mounting base and the top surface of the peripheral portion is 45 degrees or less.

3. A semiconductor laser light-emitting device comprising:
a mounting base;
a submount disposed above the mounting base;
a connecting member that connects the mounting base and the submount and is composed of a porous metal material;
a semiconductor laser disposed above the submount; and
a mirror that reflects emission light from the semiconductor laser, wherein
the submount includes a front face that is a face on a light emission side of the semiconductor laser,
the mirror is disposed above the mounting base and facing the front face of the submount,
the connecting member includes a peripheral portion that continuously covers at least part of the front face of the submount, a peripheral area of a first area of a top surface of the mounting base, and an end portion of the mirror, the first area corresponding to the submount, the end portion facing the front face of the submount,
a distance from the end portion of the mirror to the front face of the submount is less than a distance from a bottom surface of the submount to a top surface of the submount, and
a top surface of the peripheral portion is straight or recessed at a cross section that intersects the front face of the submount, the top surface of the mounting base, and the end portion of the mirror.

4. The semiconductor laser light-emitting device according to claim 1, wherein
the semiconductor laser includes a front end face located farther in a light emission direction of the semiconductor laser from the front face of the submount.

5. The semiconductor laser light-emitting device according to claim 1, wherein
a distance from a bottom surface of the submount to a position at which at least part of the top surface of the peripheral portion contacts the front face of the submount is from 40% to 100%, inclusive, of a distance from a bottom surface of the submount to a top surface of the submount.

6. The semiconductor laser light-emitting device according to claim 1, wherein
the top surface of the peripheral portion decreases in height with increasing distance from the submount.

7. The semiconductor laser light-emitting device according to claim 1, wherein
a distance from a bottom surface of the submount to a position at which the top surface of the peripheral portion contacts the front face of the submount is largest below an optical axis of the semiconductor laser.

8. The semiconductor laser light-emitting device according to claim 7, wherein
the peripheral portion covers a region that includes a straight line forming an angle of 45 degrees or less with a direction downward from the semiconductor laser, among straight lines that extend in an in-plane direction of the front face of the submount from a part at which the semiconductor laser contacts the front face of the submount.

9. The semiconductor laser light-emitting device according to claim 1, wherein
the submount includes a rear face that is a face on a rear side of the submount relative to the front face, and
a distance from a bottom surface of the submount to a position at which the top surface of the peripheral portion contacts the front face of the submount is greater than a distance from the bottom surface of the submount to a position at which the top surface of the peripheral portion contacts the rear face of the submount.

10. The semiconductor laser light-emitting device according to claim 1, wherein
a thermal conductivity of the connecting member is greater than or equal to a thermal conductivity of the submount.

11. The semiconductor laser light-emitting device according to claim 1, wherein
at a cross section of the connecting member, an atomic ratio of a metal in an area other than voids in the connecting member is 95 atomic % or more.

12. The semiconductor laser light-emitting device according to claim 1, wherein
a void ratio of the connecting member is less than 30%.

13. The semiconductor laser light-emitting device according to claim 1, wherein
the top surface of the peripheral portion includes a first recessed portion and a second recessed portion at a cross section that intersects the front face of the submount and the top surface of the mounting base.

14. The semiconductor laser light-emitting device according to claim 1, wherein
voids are formed in the peripheral portion, and
the peripheral portion includes a first region and a second region having an average size of the voids smaller than an average size of the voids in the first region.

15. A semiconductor laser light-emitting device comprising:
a mounting base;
a submount disposed above the mounting base;
a connecting member that connects the mounting base and the submount and is composed of a porous metal material; and
a semiconductor laser disposed above the submount, wherein
the submount includes a front face that is a face on a light emission side of the semiconductor laser,
the connecting member includes a peripheral portion that continuously covers at least part of the front face of the submount and a peripheral area of a first area of a top surface of the mounting base, the first area corresponding to the submount, and
a distance from a bottom surface of the submount to a position at which a top surface of the peripheral portion contacts the front face of the submount is largest below an optical axis of the semiconductor laser.

16. The semiconductor laser light-emitting device according to claim 15, wherein
the peripheral portion covers a region that includes a straight line forming an angle of 45 degrees or less with a direction downward from the semiconductor laser, among straight lines that extend in an in-plane direction of the front face of the submount from a part at which the semiconductor laser contacts the front face of the submount.

17. A method for manufacturing a semiconductor laser light-emitting device, the method comprising:
providing a semiconductor laser on a top surface of a submount;
applying first metal particles having a first particle size on a top surface of a mounting base;
disposing the submount on the first metal particles and disposing the first metal particles so as to contact a front face of the submount, the front face being a face on a light emission side of the semiconductor laser; and
applying second metal particles having a second particle size on the first metal particles.

18. The method according to claim 17, wherein
in the applying of the first metal particles, a first metal paste including the first metal particles is applied to the top surface of the mounting base,
in the applying of the second metal particles, a second metal paste including the second metal particles is applied to the first metal particles, and
a concentration of metal included in the first metal paste is higher than a concentration of metal included in the second metal paste.

19. The method according to claim 18, further comprising:
sintering the first metal particles, the sintering being performed between the applying of the first metal particles and the applying of the second metal particles.

20. The method according to claim 17, wherein
the first particle size is larger than the second particle size.
